(19) United States
(12) Patent Application Publication
(10) Pub. No.: US 2013/0240917 A1
(43) Pub. Date: Sep. 19, 2013

(54) SEMICONDUCTOR PACKAGE HAVING A CONDUCTIVE LAYER FOR ELECTROSTATIC DISCHARGE AND DISPLAY DEVICE INCLUDING THE SAME

(71) Applicant: SAMSUNG ELECTRONICS CO., LTD., Suwon-si (KR)

(72) Inventors: Kyong soon Cho, Goyang-si (KR); KwanJai Lee, Yongin-si (KR); Jae-Min Jung, Seoul (KR); Jeong-Kyu Ha, Hwaseong-si (KR); Sang-Uk Han, Hwaseong-si (KR)

(73) Assignee: Samsung Electronics Co., Ltd., Suwon-si (KR)

(21) Appl. No.: 13/780,648

(22) Filed: Feb. 28, 2013

(30) Foreign Application Priority Data
Mar. 16, 2012 (KR) 10-2012-0027359

(51) Int. Cl. H01L 23/525; H02H 9/04

(52) U.S. Cl. CPC H01L 23/5256; H02H 9/041
USPC 257/88; 257/529; 361/56

(57) ABSTRACT

A semiconductor package is provided. The semiconductor package may include a base film having a first surface and a second surface opposite the first surface, an interconnection pattern on the first surface of the base film, and a ground layer on the second surface of the base film. The semiconductor package may further include a semiconductor chip on the first surface of the base film within the first region and a via contact plug in the second region that penetrates the base film and is configured to electrically connect the interconnection pattern with the ground layer when electrostatic discharge occurs through the via contact plug.

### CROSS-REFERENCE TO RELATED APPLICATIONS

This U.S. non-provisional patent application claims priority under 35 U.S.C. §119 to Korean Patent Application No. 10-2012-0027359, filed on Mar. 16, 2012, in the Korean Intellectual Property Office (KIPO), the disclosure of which is hereby incorporated in its entirety.

### BACKGROUND

The present disclosure generally relates to the field of electronics, and more particular to a semiconductor package and a display device including the same.

It is known to provide tape packaging as a part of a flat panel display device driver chip. Examples of the tape packaging include: a tape carrier package (TCP) and a chip on film (COF). A flexible tape wiring substrate may be used in the tape packaging.

Electrostatic discharge (ESD) may be generated in a tape wiring substrate during various processes, such as a fabrication process, a test process, a visual inspection process, etc. Thus, it is possible that ESD damage to semiconductor chips in tape packaging may occur.

### SUMMARY

A semiconductor package may include a base film having a first surface and a second surface opposite the first surface and the base film may include a first region and a second region spaced apart from one another. The semiconductor package may further include an interconnection pattern on the first surface of the base film and the interconnection pattern may be in the second region and extend toward the first region. The semiconductor package may also include an insulating layer on the interconnection pattern in the second region and a ground layer on the second surface of the base film. Moreover the semiconductor package may include a semiconductor chip on the first surface of the base film within the first region and the semiconductor chip may have a bonding pad electrically connected to the interconnection pattern. Additionally, the semiconductor package may include a via contact plug in the second region penetrating the base film and the via contact plug may be configured to electrically connect the interconnection pattern with the ground layer when electrostatic discharge occurs through the via contact plug.

In various embodiments, the via contact plug may include a voltage sensitive polymer.

According to various embodiments, the interconnection pattern may comprise one among a plurality of interconnection patterns and the via contact plug may be configured to electrically connect at least two of the plurality of interconnection patterns with the ground layer when electrostatic discharge occurs through the via contact plug.

In various embodiments, the semiconductor package may further include a test pad penetrating the insulating layer and the test pad may electrically connect to the interconnection pattern.

In various embodiments, the interconnection pattern may comprise one among a plurality of interconnection patterns and the test pad may electrically connect to at least two of the plurality of interconnection patterns.

According to the various embodiments, the test pad may include a material identical to that comprising the via contact plug.

In various embodiments, the test pad may be connected to the via contact plug.

According to the various embodiments, the interconnection pattern may comprise a first interconnection pattern, the via contact plug may comprise a first via contact plug, and the base film may further comprise a third region spaced apart from the first and the second regions. Additionally the semiconductor package may further include a second interconnection pattern on the first surface of the base film and the second interconnection pattern may be in the third region and extend toward the first region. The semiconductor package may also include a second via contact plug in the third region penetrating the base film and the second via contact plug may be configured to electrically connect the second interconnection pattern with the ground layer when electrostatic discharge occurs through the second via contact plug.

In various embodiments, the base film may include polyimide.

According to the various embodiments, the interconnection pattern may include copper.

In various embodiments, the semiconductor package may further include a connecting auxiliary layer on the interconnection pattern.

According to the various embodiments, the ground layer may include copper.

In various embodiments, the semiconductor package may further include an insulating resin layer on the base film, the interconnection pattern and sides of the semiconductor chip, and between the insulating layer and the semiconductor chip.

A display device may include an array substrate including a plurality of pixels, a facing substrate facing the array substrate and configured to provide color images to a viewer of the display device, a semiconductor package for a display drive integrated circuit transmitting a drive signal to the array substrate, and a display panel including a printed circuit board transmitting a control signal to the semiconductor package for the display drive integrated circuit. The semiconductor package for the display drive integrated circuit may include a base film having a first surface and a second surface opposite the first surface and the base film may include a first region and a second region spaced apart from one another. The semiconductor package may further include an interconnection pattern on the first surface of the base film and the interconnection pattern may be in the second region and extend toward the first region. The semiconductor package may also include an insulating layer on the interconnection pattern in the second region and a ground layer on the second surface of the base film. Moreover the semiconductor package may include a semiconductor chip on the first surface of the base film within the first region and the semiconductor chip may have a bonding pad electrically connected to the interconnection pattern. Additionally, the semiconductor package may include a via contact plug in the second region penetrating the base film and the via contact plug may be configured to electrically connect the interconnection pattern with the ground layer when electrostatic discharge occurs through the via contact plug.

In various embodiments, the via contact plug may include a voltage sensitive polymer.

A wiring substrate may include a substrate having a first surface and a second surface opposite the first surface and the substrate may include a chip mounting area configured to receive a chip and an exterior area outside the chip mounting area. The wiring substrate may further include an interconnection pattern on the first surface of the substrate that is configured to be electrically connected to the chip and the interconnection pattern may be in the chip mounting area and in the exterior area. The wiring substrate may also include a ground layer on the second surface of the substrate. Moreover, the wiring substrate may include a via plug in the exterior area through the substrate and the via plug may be configured to electrically connect the interconnection pattern with the ground layer when electrostatic discharge occurs through the via plug.

In various embodiments, the via plug may include a voltage sensitive polymer.

According to various embodiments, the interconnection pattern may comprise a first interconnection pattern on a first side of the chip mounting area, and the via plug may comprise a first via plug. The wiring substrate may further include a second interconnection pattern on the first surface of the substrate that is configured to be electrically connected to the chip and the second interconnection pattern may be in the chip mounting area and in the exterior area, and on a second side of the chip mounting area. The wiring substrate may also include a second via plug in the exterior area through the substrate and the second via plug may be configured to electrically connect the second interconnection pattern with the ground layer when electrostatic discharge occurs through the second via plug.

In various embodiments, the interconnection pattern may comprise one among a plurality of interconnection patterns and the via plug may be configured to electrically connect at least two of the plurality of interconnection patterns with the ground layer.

According to various embodiments, the wiring substrate may further include an insulating layer on the interconnection pattern in the exterior area and a test pad through the insulating layer electrically connecting to the interconnection pattern.

### BRIEF DESCRIPTION OF THE FIGURES

FIG. 1 is a perspective view of a display device in accordance with various embodiments of the inventive concept.

FIGS. 2A and 2B are an upper surface and a lower surface of a semiconductor package in accordance with various embodiments of the inventive concept.

FIG. 2C is a cross-sectional view taken along the line I-I′ of FIG. 2A.

FIG. 3A is an upper surface of a semiconductor package in accordance with various embodiments of the inventive concept.

FIG. 3B is a cross-sectional view taken along the line II-II′ of FIG. 3A.

### DETAILED DESCRIPTION OF THE EMBODIMENTS

Example embodiments are described below with reference to the accompanying drawings. Many different forms and embodiments are possible without deviating from the spirit and teachings of this disclosure and so the disclosure should not be construed as limited to the example embodiments set forth herein. Rather, these example embodiments are provided so that this disclosure will be thorough and complete, and will convey the scope of the disclosure to those skilled in the art. In the drawings, the sizes and relative sizes of layers and regions may be exaggerated for clarity. Like reference numbers refer to like elements throughout.

The terminology used herein is for the purpose of describing particular embodiments only and is not intended to be limiting of the embodiments. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, integers, steps, operations, elements, and/or components, but do not preclude the presence or addition of one or more other features, integers, steps, operations, elements, components, and/or groups thereof.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein the term “and/or” includes any and all combinations of one or more of the associated listed items.

It will be understood that although the terms first, second, etc. may be used herein to describe various elements, these elements should not be limited by these terms. These terms are only used to distinguish one element from another. Thus, a first element could be termed a second element without departing from the teachings of the present embodiments.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes illustrated herein but include deviations in shapes that result, for example, from manufacturing. Thus, the elements illustrated in the figures are schematic in nature and their shapes may not illustrate the actual shapes of the elements and are not intended to limit the scope of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein may be interpreted accordingly.

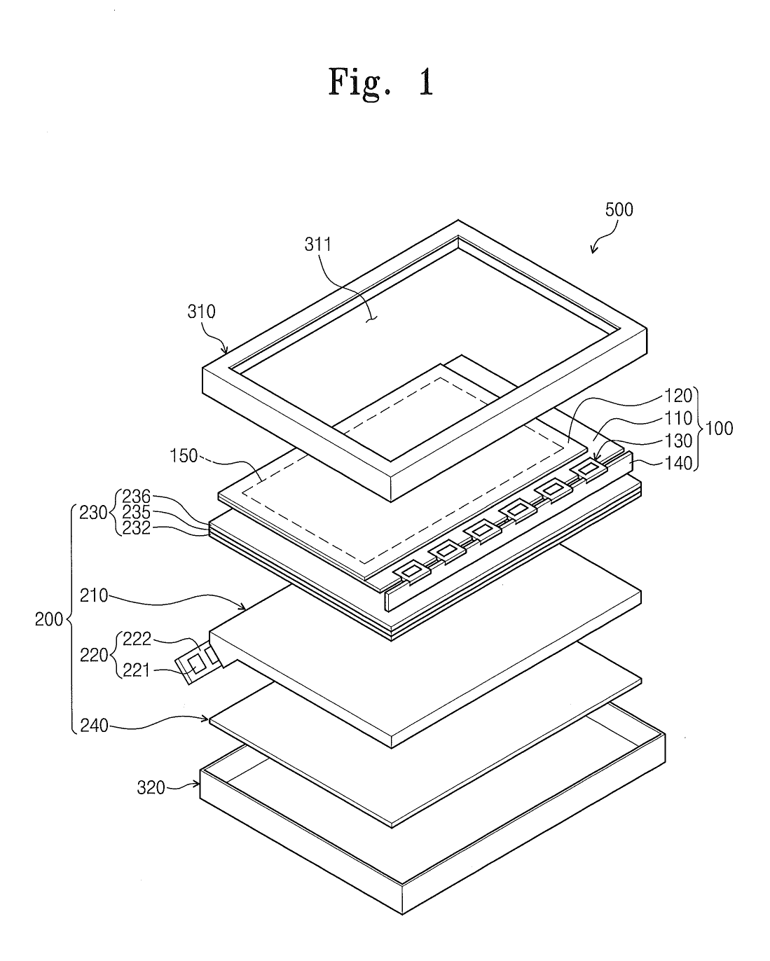

FIG. 1 is a perspective view of a display device in accordance with various embodiments of the inventive concept.

Referring to FIG. 1, a display device 500 includes a display panel 100, a back light unit (BLU) 200, an upper cover 310 and a lower cover 320.

Various display panel such as a liquid crystal display (LCD) panel, an electrophoretic display panel (EDP) and an organic light emitting diode (OLED) may be used as the display device 100. In various embodiments of the inventive concept, a liquid crystal display (LCD) panel is used as the display device 100.

The display panel 100 is prepared by a rectangular plate. The display panel 100 includes an array substrate 110, a facing substrate 120 facing the array substrate 110 and a liquid crystal layer formed between the array substrate 110 and the facing substrate 120.

According to various embodiments of the inventive concept, the array substrate 110 may include a lot of pixels arranged in the matrix form. Each pixel includes a pixel electrode. A gate line extending in a first direction parallel to one side of the array substrate 110 and a data line extending in a second direction crossing the first direction to cross the gate line are disposed around the pixel electrode. The gate line is insulated from the data line. Each pixel includes a thin film transistor (TFT) electrically connected to the gate line, the data line and the pixel electrode. The thin film transistor (TFT) switches a drive signal being provided to a corresponding pixel electrode. A semiconductor package 130 for display driver integrated (DDI) circuit may be disposed in one side of the array substrate 110. The semiconductor package 130 for display driver integrated (DDI) circuit may receive signals from a printed circuit board 140 electrically connected to the outside and outputs a drive signal driving the display panel 100 in response to the received signals.

The facing substrate 120 may be configured to provide color images to a viewer of the display device 500. The facing substrate 120 may include an RGB color filter realizing a predetermined color on one surface of the facing substrate 120 using a light and a common electrode which is formed on the RGB color filter to face a pixel electrode. The RGB color filter can be formed using a thin film process. In various embodiments of the inventive concept, the RGB color filter is formed on the facing substrate 120 but the inventive concept is not limited thereto. The RGB color filter may be formed on the array substrate 110.

Since the liquid crystal layer is arranged in a specific direction by a voltage applied to a pixel electrode and a common electrode, transmittance of light provided from the backlight unit 200 is controlled and thereby the display panel 100 can display an image.

The backlight unit 200 is located at a lower portion of the display panel 100. The backlight 200 includes a light guide plate (LGP) 210, a light source unit 220, an optical member 230 and a reflective sheet 240.

The light guide plate (LGP) 210 is located at a lower portion of the display panel 100 and guides a light emitted from the light source unit 220 to output the light to the display panel 100.

The light source unit 220 may be constituted in the form that a plurality of light sources 221 is mounted in the printed circuit board 222. Each light source 221 may be a light emitting diode (LED).

The optical member 230 is disposed between the light guide plate (LGP) 210 and the display panel 100. The optical member 230 controls a light emitted from the light source unit 220. The optical member 230 may include a diffusion sheet 232, a prism sheet 235 and a protection sheet 236 that are sequentially stacked on the light guide plate (LGP) 210.

The diffusion sheet 232 spreads a light emitted from the light source unit 220. The prism sheet 235 concentrates light spread in the diffusion sheet 232 in a direction perpendicular to a plane of the display panel 100. Almost the whole light which passes through the prism sheet 235 vertically enters the display panel 100. The protection sheet 236 is disposed on the prism sheet 235 to protect the prism sheet 235 from an external shock.

In various embodiments of the inventive concept, the optical member 230 may include one diffusion sheet 232, one prism sheet 235 and one protection sheet 236 but the inventive concept is not limited thereto. Any one of the diffusion sheet 232, the prism sheet 235 and the protection sheet 236 may be used to be plurally overlapped. Any one of the diffusion sheet 232, the prism sheet 235 and the protection sheet 236 may be omitted when necessary. For instance, two overlapped prism sheets may be used.

The reflective sheet 240 is disposed in a lower portion of the light guide plate (LGP) 210. The reflective sheet 240 reflects a leakage light that is not provided to the display panel 100 to change a light path into the display panel 100. The reflective sheet 240 may include a material reflecting a light. The reflective sheet 240 is disposed on the lower cover 320 to reflect a light generated from the light source unit 220. As a result, the reflective sheet 240 increases the quantity of light being provided to the display panel 100.

The upper cover 310 is disposed on an upper portion of the display panel 100 and is made in a shape corresponding to a shape of the display panel 100. The upper cover 310 includes a display window 311 exposing a display area 150 of the display panel 100, a top surface supporting a front edge of the display panel 100 and upper cover sides extending from the top surface and bending toward the lower cover 320. Since the display panel 100 is a tetragonal plate, the upper cover 310 may include four upper cover sides. The upper cover 310 combines with the lower cover 320 to support a front edge of the display panel 100.

The lower cover 320 is disposed at a lower portion of the backlight unit 200. The lower cover 320 includes a bottom surface corresponding to a shape of the display panel 100 and the backlight unit 200 and lower cover sides extending from the bottom surface and bending upward. Since the display panel 100 is a tetragonal plate, the lower cover 320 may include four lower cover sides. The lower cover 320 has a space that can accommodate the display panel 100 and the backlight unit 200 by the bottom surface and the lower cover sides. The lower cover 320 combines with the upper cover 310 to accommodate the display panel 100 and the backlight unit 200 in the internal space and support them.

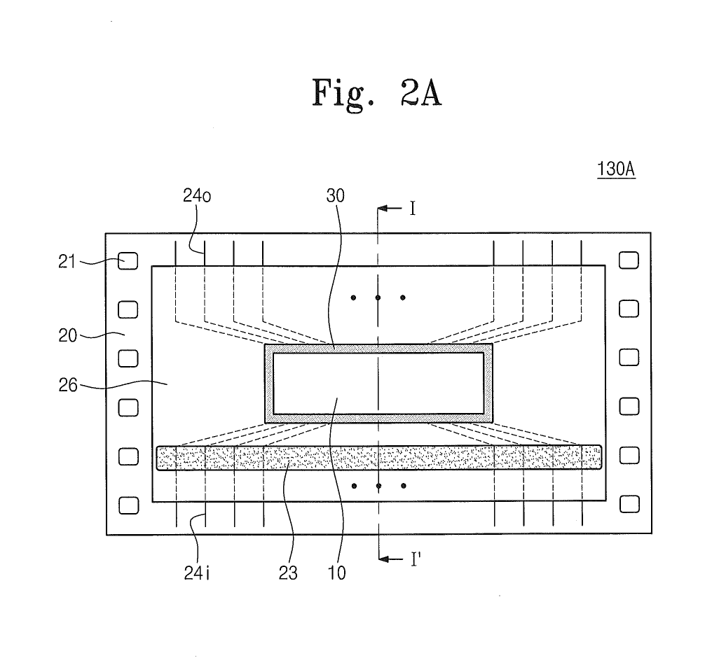

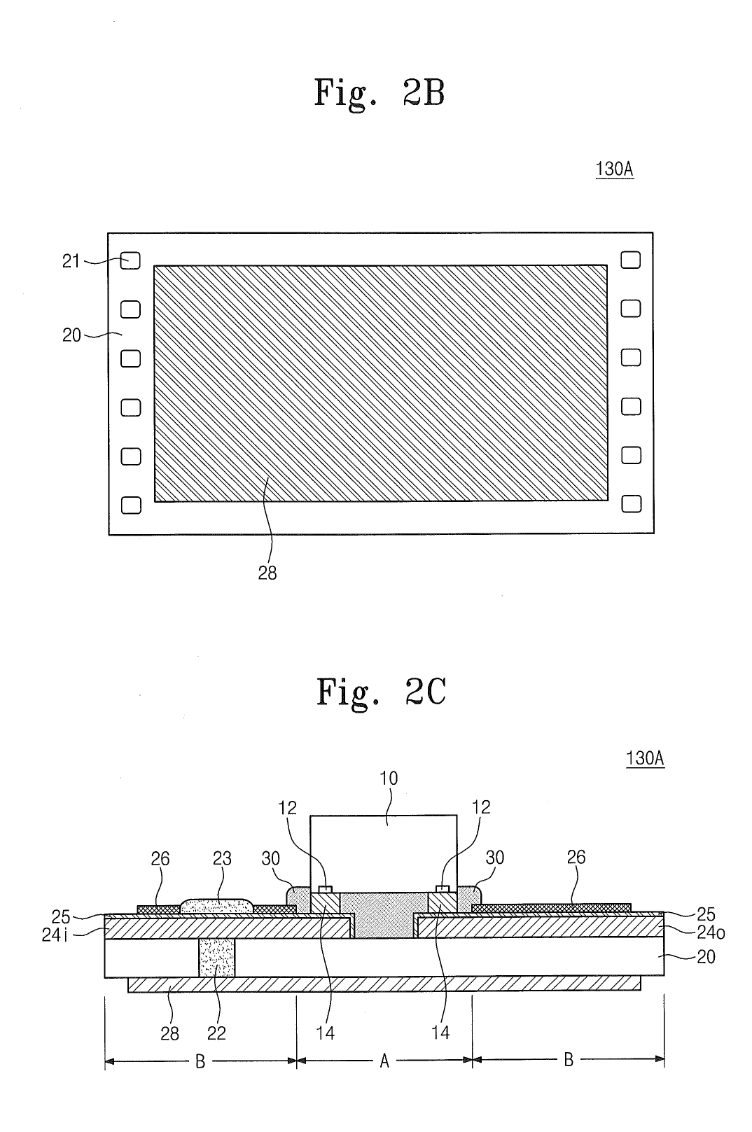

FIGS, 2A and 2B are an upper surface and a lower surface of a semiconductor package in accordance with various embodiments of the inventive concept. FIG. 2C is a cross-sectional view taken along the line I-I′ of FIG. 2A.

Referring to FIGS. 2A through 2C, a semiconductor package 130A may be a semiconductor package for display drive integrated circuit used a display panel (100 of FIG. 1) of display device (500 of FIG. 1).

The semiconductor package 130A may include a wiring substrate, a semiconductor chip 10 and an insulating resin layer 30. The wiring substrate may include a base film 20, interconnection patterns 24i and 24o and an insulating layer 26 provided on a top surface of the base film 20. The wiring substrate may further include a ground layer 28 provided on a bottom surface of the base film 20 and via contact plug 22 that penetrates the base film 20 and is configured to electrically connect the interconnection patterns 24i and 24o with the ground layer 28 when electrostatic discharge occurs through the via contact plug 22.

The base film 20 may have a mounting area A on which the semiconductor chip 10 is mounted and an exterior area B outside the mounting area A. The base film 20 may include a polyimide (PI).

The ground layer 28 including a conductive material may absorb and disperse static electricity to protect a device from electrostatic discharge damage. The ground layer 28 may include copper (Cu). Although the term “ground layer” is used herein, it will be understood that the element 28 can be any conductive layer that is electrically isolated from protected components sufficiently so as to provide protection from ESD.

The interconnection patterns 24i and 24o may be constituted by input interconnections 24i for inputting a signal to the semiconductor chip 10 and output interconnections 24o for outputting a signal received from the semiconductor chip 10. The input interconnections 24i and the output interconnections 24o may be disposed to face each other. The interconnection patterns 24i and 24o may include copper (Cu).

The wiring substrate may further include a metal seed layer interposed between the interconnection patterns 24i and 24o and the base film 20. The metal seed layer can perform a function of electrode in an electroplating process forming the interconnection patterns 24i and 24o.

The interconnection patterns 24i and 24o can perform a function of inner lead because they have an exposed surface in the mounting area A of the wiring substrate.

The interconnection patterns 24i and 24o can perform a function of outer lead because their surfaces are covered by the insulating layer 26 in the exterior area B and are exposed at edges spaced apart from the mounting area A.

The base film 20 may include sprocket holes 21 penetrating the base film 20. The sprocket holes 21 may be disposed on edges of the base film 20 facing each other with respect to the semiconductor chip 10 on which the input interconnections 24i and the output interconnections 24o are not disposed because the input interconnections 24i and the output interconnections 24o are disposed to face each other with respect to the semiconductor chip 10. The sprocket holes 21 provide a wiring substrate to mounting equipment mounting the semiconductor chip 10 on each of a plurality of connected wiring substrates.

The via contact plug 22 penetrating the base film 20 of the exterior area B is configured to electrically connect one of the interconnection patterns 24i to the ground layer 28 when electrostatic discharge occurs through the via contact plug 22. Thus, electrostatic discharge applied to the input interconnections 24i can be dispersed into the ground layer 28.

The via contact plug 22 may include a voltage switchable dielectric material that is non-conductive but can be switched to become conductive by being applied a voltage having a magnitude that exceeds a characteristic voltage of the material. For example, the via contact plug 22 may include a voltage sensitive polymer that has a characteristic of maintaining an insulating property usually and having conductivity when electrostatic discharge is applied.

Examples of voltage sensitive polymers includes various reported mixtures of polymers and conductive particles, for example, a material formed from a 35% polymer binder, 0.5% cross linking agent, and 64.5% conductive powder. The polymer binder may include Silastic 35U silicone rubber, the cross linking agent may include Varox peroxide, and the conductive powder may include nickel with 10 micron average particle size. Other examples of conductive particles include aluminum, beryllium, iron, silver, platinum, lead, tin, bronze, brass, copper, bismuth, cobalt, magnesium, molybdenum, palladium, tantalum carbide, boron carbide, and other conductive materials that can be dispersed within a material such as a binding agent.

The via contact plug 22 may contact both one of the input interconnections 24i and one of the output interconnections 24o and those input interconnections 24i and output interconnections 24o may be electrically connected with the ground layer 28 when electrostatic discharge occurs through the via contact plug 22. The via contact plug 22 may contact both one of the input interconnections 24i and one of the output interconnections 24o in any appropriate manners and through any appropriate means. For example, the via contact plug 22 may be a line pattern extending on or within the base film 20.

The via contact plug 22 may contact several input interconnections 24i to electrically connect those input interconnections 24i with the ground layer 28 when electrostatic discharge occurs through the via contact plug 22. The via contact plug 22 may contact several input interconnections 24i in any appropriate manners and through any appropriate means. For example, the via contact plug 22 may be a line pattern extending on or within the base film 20.

A connecting auxiliary layer 25 may be disposed on the interconnection patterns 24i and 24o. The connecting auxiliary layer 25 can perform a function of medium providing an electrical connection between bumps 14 provided on bonding pads 12 of the semiconductor chip 10 and the wiring substrate. The connecting auxiliary layer 25 can prevent an oxidation of the interconnection patterns 24i and 24o from external environment.

The insulating layer 26 may be disposed on the exterior area B. The insulating layer 26 may include solder resist. The insulating layer 26 is disposed on the exterior area B of the wiring substrate to protect the wiring substrate including the interconnection patterns 24i and 24o from an external environment.

A test pad 23 penetrating the insulating layer 26 to be electrically connected to the interconnection patterns 24i and 24o may be further provided. The test pad 23 may electrically connect to both one of the input interconnections 24i and one of the output interconnections 24o. The test pad 23 may electrically connect to several input interconnections 24i. Electrical connections between the test pad 23 and both one of the input interconnections 24i and one of the output interconnections 24o and the test pad 23 and several input interconnections 24i may be in any appropriate manners and through any appropriate means. For example, the test pad 23 may be a line pattern extending on or within the base film 20.

The test pad 23 may include a conductive material or a material identical to that comprising the via contact plug 22. If the test pad 23 includes the material identical to that comprising the via contact plug 22, the test pad 23 may have a structure that it is directly connected to the via contact plug 22. The test pad 23 may be formed with the via contact plug 22 through the same process.

The test pad 23 can perform a function of pad for applying electrostatic discharge on experiment.

The semiconductor chip 10 may be mounted so that an active face of the semiconductor chip 10 contacts the mounting area A of the wiring substrate. The semiconductor chip 10 may include the bonding pads 12 disposed on the active face of the semiconductor chip 10.

The insulating resin layer 30 may be disposed between the wiring substrate and the semiconductor chip 10 and on sides of the semiconductor chip 10. The insulating resin layer 30 can protect the interconnection patterns 24i and 24o inside the mounting area A corresponding to the internal lead from an external environment and can protect the semiconductor chip 10 of the semiconductor package 130A from an external environment.

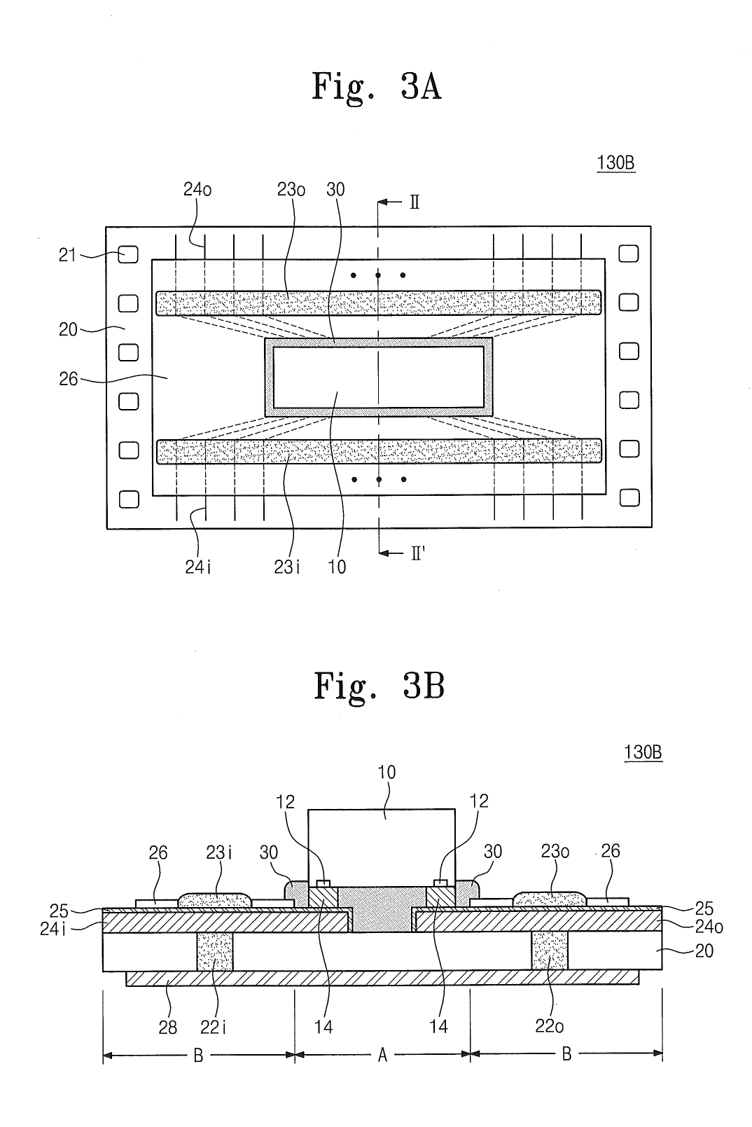

FIG. 3A is an upper surface of a semiconductor package in accordance with various embodiments of the inventive concept. FIG. 3B is a cross-sectional view taken along the line II-II′ of FIG. 3A. For convenience of description, in FIGS. 3A and 3B, different points from FIGS. 2A through 2C will be mainly described. In semiconductor package 130B described with reference to FIGS. 3A and 3B, a via contact plug 22o is further provided.

The via contact plugs 22i and 22o may include an input via contact plug 22i connecting the input interconnections 24i with the ground layer 28 and an output via contact plug 22o connecting the output interconnections 24o with the ground layer 28. The via contact plugs 22i and 22o penetrating the base film 20 of the exterior area B are configured to electrically connect the interconnection patterns 24i and 24o with the ground layer 28 when electrostatic discharge occurs through the via contact plugs 22i and 22o. Therefore, electrostatic discharge applied to the input interconnections 24i can be discharged into the ground layer 28 through the input via contact plug 22i without passing through the semiconductor chip 10.

The input via contact plug 22i may contact both one of the input interconnections 24i and one of the output interconnections 24o and those input interconnections 24i and output interconnections 24o may be electrically connected with the ground layer 28 when electrostatic discharge occurs through input via contact plug 22i. The output via contact plug 22o may also contact both one of the input interconnections 24i and one of the output interconnections 24o.

The input via contact plug 22i may contact several input interconnections 24i to electrically connect those input interconnections 24i with the ground layer 28 when electrostatic discharge occurs through the input via contact plug 22i. The output via contact plug 22o may also contact several output interconnections 24o to electrically connect those output interconnections 24o with the ground layer 28 when electrostatic discharge occurs through the output via contact plug 22o.

Test pads 23i and 23o may be further provided and may include an input test pad 23i on the input interconnections 24i and an output test pad 23o on the output interconnections 24o. Test pads 23i and 23o penetrate the insulating layer 26 to be electrically connected to the interconnection patterns 24i and 24o, respectively.

The input test pad 23i may electrically connect to both one of the input interconnections 24i and one of the output interconnections 24o. The output test pad 23o may also electrically connect to both one of the input interconnections 24i and one of the output interconnections 24o. The input test pad 23i may electrically connect to several input interconnections 24i and the output test pad 23o may electrically connect to several output interconnections 24o.

The test pads 23i and 23o can perform a function of a pad for applying electrostatic discharge on experiment.

The above-disclosed subject matter is to be considered illustrative, and not restrictive, and the appended claims are intended to cover all such modifications, enhancements, and other embodiments, which fall within the true spirit and scope. Thus, to the maximum extent allowed by law, the scope is to be determined by the broadest permissible interpretation of the following claims and their equivalents, and shall not be restricted or limited by the foregoing detailed description.

What is claimed is:

1. A semiconductor package comprising:
a base film having a first surface and a second surface opposite the first surface, the base film comprising a first region and a second region spaced apart from one another;
an interconnection pattern on the first surface of the base film, the interconnection pattern being in the second region and extending toward the first region;
an insulating layer on the interconnection pattern in the second region;
a ground layer on the second surface of the base film;
a semiconductor chip on the first surface of the base film within the first region, the semiconductor chip having a bonding pad electrically connected to the interconnection pattern; and
a via contact plug in the second region penetrating the base film, the via contact plug being configured to electrically connect the interconnection pattern with the ground layer when electrostatic discharge occurs through the via contact plug.

2. The semiconductor package of claim 1, wherein the via contact plug comprises a voltage sensitive polymer.

3. The semiconductor package of claim 1, wherein the interconnection pattern comprises one among a plurality of interconnection patterns and the via contact plug is configured to electrically connect at least two of the plurality of interconnection patterns with the ground layer when electrostatic discharge occurs through the via contact plug.

4. The semiconductor package of claim 1, further comprising a test pad penetrating the insulating layer, the test pad electrically connecting to the interconnection pattern.

5. The semiconductor package of claim 4, wherein the interconnection pattern comprises one among a plurality of interconnection patterns and the test pad electrically connects to at least two of the plurality of interconnection patterns.

6. The semiconductor package of claim 4, wherein the test pad comprises a material identical to that comprising the via contact plug.

7. The semiconductor package of claim 6, wherein the test pad is connected to the via contact plug.

8. The semiconductor package of claim 1, wherein the interconnection pattern comprises a first interconnection pattern, the via contact plug comprises a first via contact plug, the base film further comprises a third region spaced apart from the first and the second regions, and the semiconductor package further comprising:
a second interconnection pattern on the first surface of the base film, the second interconnection pattern being in the third region and extending toward the first region; and
a second via contact plug in the third region penetrating the base film, the second via contact plug being configured to electrically connect the second interconnection pattern with the ground layer when electrostatic discharge occurs through the second via contact plug.

9. The semiconductor package of claim 1, wherein the base film comprises polyimide.

10. The semiconductor package of claim 1, wherein the interconnection pattern comprises copper.

11. The semiconductor package of claim 1, further comprising a connecting auxiliary layer on the interconnection pattern.

12. The semiconductor package of claim 1, wherein the ground layer comprises copper.

13. The semiconductor package of claim 1, further comprising an insulating resin layer on the base film, the interconnection pattern and sides of the semiconductor chip, and between the insulating layer and the semiconductor chip.

14. A display device comprising:
an array substrate including a plurality of pixels;
a facing substrate facing the array substrate and configured to provide color images to a viewer of the display device;
a semiconductor package for a display drive integrated circuit transmitting a drive signal to the array substrate; and
a display panel including a printed circuit board transmitting a control signal to the semiconductor package for the display drive integrated circuit,
wherein the semiconductor package for the display drive integrated circuit comprises:
a base film having a first surface and a second surface opposite the first surface, the base film comprising a first region and a second region spaced apart from one another;
an interconnection pattern on the first surface of the base film, the interconnection pattern being in the second region and extending toward the first region;
an insulating layer on the interconnection pattern in the second region;
a ground layer on the second surface of the base film;
a semiconductor chip on the first surface of the base film within the first region, the semiconductor chip having a bonding pad electrically connected to the interconnection pattern; and
a via contact plug in the second region penetrating the base film, the via contact plug being configured to electrically connect the interconnection pattern with the ground layer when electrostatic discharge occurs through the via contact plug.

15. The display device of claim 14, wherein the via contact plug comprises a voltage sensitive polymer.

16. A wiring substrate comprising:
a substrate having a first surface and a second surface opposite the first surface, the substrate including a chip mounting area configured to receive a chip and an exterior area outside the chip mounting area;
an interconnection pattern on the first surface of the substrate that is configured to be electrically connected to the chip, the interconnection pattern being in the chip mounting area and in the exterior area;
a ground layer on the second surface of the substrate; and
a via plug in the exterior area through the substrate, the via plug being configured to electrically connect the interconnection pattern with the ground layer when electrostatic discharge occurs through the via plug.

17. The wiring substrate of claim 16, wherein the via plug comprises a voltage sensitive polymer.

18. The wiring substrate of claim 16, wherein the interconnection pattern comprises a first interconnection pattern on a first side of the chip mounting area, the via plug comprises a first via plug, and the wiring substrate further comprising:
a second interconnection pattern on the first surface of the substrate that is configured to be electrically connected to the chip, the second interconnection pattern being in the chip mounting area and in the exterior area, and on a second side of the chip mounting area; and
a second via plug in the exterior area through the substrate, the second via plug being configured to electrically connect the second interconnection pattern with the ground layer when electrostatic discharge occurs through the second via plug.

19. The wiring substrate of claim 16, wherein the interconnection pattern comprises one among a plurality of interconnection patterns and the via plug is configured to electrically connect at least two of the plurality of interconnection patterns with the ground layer.

20. The wiring substrate of claim 16, further comprising:
an insulating layer on the interconnection pattern in the exterior area; and
a test pad through the insulating layer electrically connecting to the interconnection pattern.
